(19) United States
(12) Patent Application Publication
(10) Pub. No.: US 2026/0269802 A1
(43) Pub. Date: Sep. 10, 2026

(54) BALANCED FILTER

(71) Applicant: Murata Manufacturing Co., Ltd., Nagaokakyo-shi (JP)

(72) Inventors: Akira HIRAO, Nagaokakyo-shi (JP); Yasushi YUNOKI, Nagaokakyo-shi (JP)

(21) Appl. No.: 19/533,899

(22) Filed: Feb. 9, 2026

(30) Foreign Application Priority Data
Mar. 5, 2025 (JP) 2025-034499

(51) Int. Cl. H03H 7/42; H03H 1/00; H03H 7/01

(52) U.S. Cl. CPC H03H 7/42; H03H 1/0007; H03H 7/1791; H03H 2001/0085

(57) ABSTRACT

A balanced filter includes dielectric layers, an unbalanced terminal, first and second balanced terminals, a direct-current power supply terminal, a ground terminal, a filter circuit, a balun, first and second ground electrodes, and ground vias. The unbalanced terminal, the first and second balanced terminals, the direct-current power supply terminal, and the ground terminal are on an outer surface of the multilayer body. The filter circuit is connected to the unbalanced terminal and includes resonators in the multilayer body. The balun is connected to the first and second balanced terminals. The first ground electrode is on or in a dielectric layer between the filter circuit and a second major surface and connected to the ground terminal. The second ground electrode is on or in a dielectric layer between the first ground electrode and the second major surface and connected to the ground terminal.

### CROSS REFERENCE TO RELATED APPLICATIONS

This application claims the benefit of priority to Japanese Patent Application No. 2025-034499 filed on Mar. 5, 2025. The entire contents of this application are hereby incorporated herein by reference.

### BACKGROUND OF THE INVENTION

### 1. Field of the Invention

The present disclosure relates to balanced filters. More specifically, the present disclosure relates to technologies to prevent degradation of characteristics of balanced filters each including a direct-current power supply terminal.

### 2. Description of the Related Art

Japanese Unexamined Patent Application Publication No. 2005-260903 discloses a configuration of a balanced filter that is used for radio communication devices and in which a direct-current power supply voltage is supplied from a direct-current power supply to a balun disposed on a transmission path.

When balanced signals are input to the balun to which a direct-current power supply voltage is supplied, the balanced signals with a direct-current bias applied are converted into an unbalanced signal. The direct-current power supply may also be used as a power supply for a semiconductor circuit, such as a differential amplifier, provided in an integrated circuit (RFIC) that outputs a transmission signal to the balun.

In a balanced filter supplied with a direct-current power supply voltage, a direct-current power supply line is provided together with a filter circuit and a balun in a multilayer substrate formed by laminating multiple dielectric layers. In this case, depending on the path of the direct-current power supply line in the multilayer substrate, coils included in the filter circuit and/or the balun may be electromagnetically coupled to the direct-current power supply line. This influences characteristics, such as amplitude balance and a phase difference, and makes it difficult to achieve desired filter characteristics of the balanced filter.

### SUMMARY OF THE INVENTION

Example embodiments of the present invention provide balanced filters in each of which degradation of characteristics of the balanced filter supplied with a direct-current power supply voltage is reduced or prevented.

A balanced filter according to an example embodiment of the present invention includes a multilayer body including multiple dielectric layers that are laminated, an unbalanced terminal, a first balanced terminal, a second balanced terminal, a direct-current power supply terminal, a ground terminal, a filter circuit, a balun, first and second ground electrodes with a planar shape, and multiple ground vias. The multilayer body includes a first major surface and a second major surface that face each other. The unbalanced terminal, the first balanced terminal, the second balanced terminal, the direct-current power supply terminal, and the ground terminal are provided on an outer surface of the multilayer body. The filter circuit is connected to the unbalanced terminal and includes multiple resonators in the multilayer body. The balun is connected to the first balanced terminal and the second balanced terminal to convert balanced signals into an unbalanced signal. The first ground electrode is provided on or in a dielectric layer between the filter circuit and the second major surface and is connected to the ground terminal. The second ground electrode is provided on or in a dielectric layer between the first ground electrode and the second major surface and is connected to the ground terminal. The multiple ground vias connect the first ground electrode to the second ground electrode. The balun includes a first inductor, a second inductor, and a direct-current power supply line. The first inductor and the second inductor are electromagnetically coupled to at least one of the resonators of the filter circuit and are connected, respectively, to the first balanced terminal and the second balanced terminal. The direct-current power supply line is connected between the direct-current power supply terminal and a connection node between the first inductor and the second inductor. A portion of the direct-current power supply line is provided on or in a dielectric layer between the first ground electrode and the second ground electrode.

In balanced filters according to example embodiments of the present invention, a portion of the direct-current power supply line to supply a direct-current power supply voltage is provided in a dielectric layer between two planar ground electrodes that are interconnected by multiple ground vias. With this configuration, the ground electrodes define and function as a shield for the filter circuit and the balun and reduce or prevent the electromagnetic coupling between each of the filter circuit and the balun and the direct-current power supply line. This in turn makes it possible to reduce or prevent an influence on filter characteristics resulting from the electromagnetic coupling with the direct-current power supply line and to reduce or prevent the degradation of characteristics of the balanced filter.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic overall configuration diagram of a communication device in which a balanced filter according to an example embodiment of the present invention is provided.

FIG. 2 is an equivalent circuit of the balanced filter illustrated in FIG. 1.

FIG. 3 is an external perspective view of the balanced filter illustrated in FIG. 1.

FIG. 4 is an exploded perspective view of the balanced filter illustrated in FIG. 1.

FIG. 5 is a diagram for describing filter characteristics of a balanced filter according to an example embodiment of the present invention.

FIG. 6 is a diagram for describing positions of ground vias.

FIG. 7 is a diagram for describing influences of the ground vias in FIG. 6 on filter characteristics.

FIG. 8 is a diagram for describing a relationship between amplitude balance and a distance from a short side of a multilayer body to each ground via.

FIG. 9 is a diagram illustrating a first variation of an external terminal position according to an example embodiment of the present invention.

FIG. 10 is a diagram illustrating a second variation of external terminal positions according to an example embodiment of the present invention.

### DETAILED DESCRIPTION OF THE EXAMPLE EMBODIMENTS

Example embodiments of the present invention are described in detail below with reference to the drawings. The same reference number is assigned to the same or similar components in the drawings, and the descriptions of those components are not repeated.

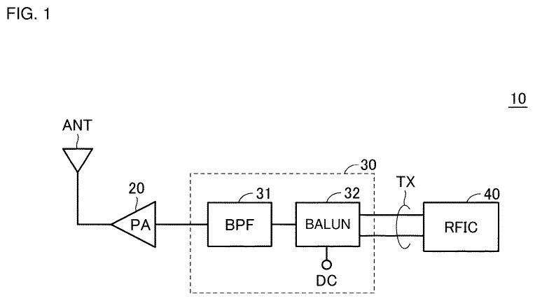

FIG. 1 is a block diagram illustrating a communication device 10 according to an example embodiment of the present invention. The communication device 10 is, for example, a mobile terminal, such as a smartphone, or a mobile phone base station.

Referring to FIG. 1, the communication device 10 includes an antenna ANT, a power amplifier (PA) 20, a balanced filter 30, and an RF circuit (RFIC) 40. The balanced filter 30 includes a filter circuit 31 and a balun 32. The filter circuit 31 is, for example, a band pass filter (BPF). FIG. 1 illustrates an example in which the communication device 10 includes a transmission circuit that transmits radio frequency signals from the antenna ANT. However, the communication device 10 may also include a reception circuit that receives radio frequency signals via the antenna ANT.

The communication device 10 emits, from the antenna ANT, a transmission signal TX received from the RF circuit 40. The balanced filter 30 converts the transmission signal TX, which is transmitted as balanced signals from the RF circuit 40, into an unbalanced signal by using the balun 32 and passes only signal components in a frequency band defined by a communication standard by using the filter circuit 31. A radio frequency signal that has passed through the balanced filter 30 is amplified by the power amplifier 20 to a predetermined power level and is emitted as a radio wave via the antenna ANT.

The balun 32 includes a direct-current power supply terminal DC to receive a direct-current power supply voltage from an external source. When receiving a direct-current voltage at the direct-current power supply terminal DC, the balun 32 converts balanced signals, which are input to the balun 32 and to which a direct-current bias is applied, into an unbalanced signal. The direct-current voltage may also be used as a voltage supplied to a semiconductor circuit, such as a differential amplifier, that is provided in the RF circuit 40 for outputting the transmission signal TX to the balun 32.

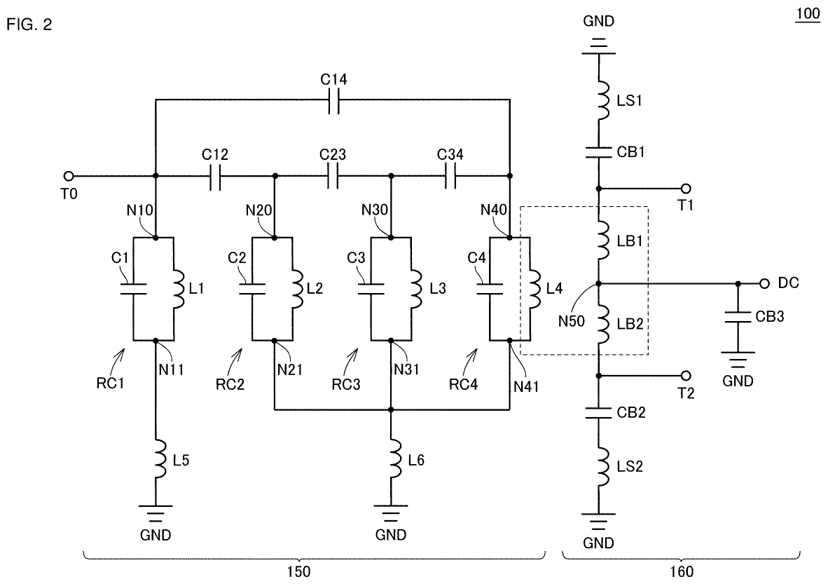

Next, a detailed configuration of a balanced filter 100 according to the present example embodiment is described with reference to FIGS. 2 to 4. The balanced filter 100 corresponds to the balanced filter 30 in FIG. 1.

FIG. 2 is an equivalent circuit diagram of the balanced filter 100. The balanced filter 100 includes an unbalanced terminal T0, balanced terminals T1 and T2, a direct-current power supply terminal DC, a ground terminal GND, a filter circuit 150 corresponding to the filter circuit 31 in FIG. 1, and a balun 160 corresponding to the balun 32 in FIG. 1.

In the example of the balanced filter 100 of the present example embodiment, the filter circuit 150 is a four-stage band pass filter and includes resonators RC1 to RC4, which are LC parallel resonators, capacitors C12, C14, C23, and C34, and inductors L5 and L6. The number of resonators of the filter circuit 150 is not limited to this example.

The resonator RC1 includes a capacitor C1 and an inductor L1 that are connected in parallel. A connection node N10 between the capacitor C1 and the inductor L1 is connected to the unbalanced terminal T0. Another connection node N11 between the capacitor C1 and the inductor L1 is connected to the ground terminal GND via the inductor L5.

The resonator RC2 includes a capacitor C2 and an inductor L2 that are connected in parallel. A connection node N20 between the capacitor C2 and the inductor L2 is connected to the unbalanced terminal T0 via the capacitor C12. Another connection node N21 between the capacitor C2 and the inductor L2 is connected to the ground terminal GND via the inductor L6.

The resonator RC3 includes a capacitor C3 and an inductor L3 that are connected in parallel. A connection node N30 between the capacitor C3 and the inductor L3 is connected, via the capacitor C23, to a connection node between the capacitor C12 and the resonator RC2 (that is, the connection node N20). Another connection node N31 between the capacitor C3 and the inductor L3 is connected to the ground terminal GND via the inductor L6.

The resonator RC4 includes a capacitor C4 and an inductor L4 that are connected in parallel. A connection node N40 between the capacitor C4 and the inductor L4 is connected, via the capacitor C34, to a connection node between the capacitor C23 and the resonator RC3 (that is, the connection node N30). Another connection node N41 between the capacitor C4 and the inductor L3 is connected to the ground terminal GND via the inductor L6. In other words, the inductor L6 is shared by the resonators RC2 to RC4.

The capacitor C14 is connected between the connection node N10 of the resonator RC1 and the connection node N40 of the resonator RC4.

The resonators RC1 to RC4 are electromagnetically coupled to each other by generated electromagnetic fields. Also, the resonator RC1 and the resonator RC2 are capacitively coupled by the capacitor C12. The resonator RC2 and the resonator RC3 are capacitively coupled by the capacitor C23. The resonator RC3 and the resonator RC4 are capacitively coupled by the capacitor C34. The resonator RC1 and the resonator RC4 are capacitively coupled by the capacitor C14.

The filter circuit 150 defines and functions as a band pass filter that selectively passes signals in a predetermined frequency band by adjusting the resonant frequencies of the resonators RC1 to RC4. The balun 160 includes inductors LB1, LB2, LS1, and LS2 and capacitors CB1 to CB3.

The inductors LB1 and LB2 are coils with the same or substantially the same electrical length, and a first end of the inductor LB1 and a first end of the inductor LB2 are connected to each other.

A second end of the inductor LB1 is connected to the balanced terminal T1 of the two balanced terminals. The second end of the inductor LB1 is also connected to a first end of the capacitor CB1. A second end of the capacitor CB1 is connected to the ground terminal GND via the inductor LS1.

A second end of the inductor LB2 is connected to the balanced terminal T2 of the two balanced terminals. The second end of the inductor LB2 is also connected to a first end of the capacitor CB2. A second end of the capacitor CB2 is connected to the ground terminal GND via the inductor LS2.

The capacitors CB1 and CB2 connected between the balanced terminals T1 and T2 and the ground terminal GND are provided to adjust the balance characteristics of the balun 160.

The inductors LB1 and LB2 are magnetically coupled to at least the inductor L4 of the resonator RC4. The inductors LB1 and LB2 define and function as balanced-side inductors and the inductor L4 defines and functions as an unbalanced-side inductor to implement the balun. Balanced signals received by the balanced terminals T1 and T2 are converted into an unbalanced signal and transferred to the inductor L4, i.e., the resonator RC4. The signal transferred to the resonator RC4 passes through the resonators RC1 to RC3 and is output from the unbalanced terminal T0.

The balun defined by the inductors LB1, LB2, and L4 is, for example, a Marchand balun. In this case, when the center wavelength of the frequency band of a radio frequency signal to be transmitted is λ, the inductors LB1 and LB2 are set as one-end-open resonators, and the inductor L4 is set as a two-end-open resonator. One half of the inductor L4 is coupled to the inductor LB1, and the other half is coupled to the inductor LB2. Here, a balun other than a Marchand balun may also be used as long as it can convert balanced signals into an unbalanced signal.

When balanced signals with equal or substantially equal amplitudes and inverted phases are supplied to the balanced terminals T1 and T2, the two balanced signals are combined at the inductor L4 and output from the unbalanced terminal T0 via the filter circuit 150.

A connection node N50 between the inductors LB1 and LB2 is connected to the direct-current power supply terminal DC. The connection node N50 is also connected to the ground terminal GND via the capacitor CB3. The capacitor CB3 defines and functions as a bypass capacitor for high-frequency suppression.

The direct-current power supply terminal DC receives a direct-current power supply voltage from a direct-current power supply (not shown) outside the balanced filter 100. With the direct-current power supply voltage supplied to the direct-current power supply terminal DC, a direct-current bias is applied to the balanced signals supplied to the balanced terminals T1 and T2. The direct-current power supply voltage supplied to the direct-current power supply terminal DC may also be used as power that is supplied via the balanced terminals T1 and T2 to a semiconductor circuit, such as a differential amplifier, for example, included in the RF circuit 40.

In the equivalent circuit of FIG. 2, the shunt inductors L5, L6, LS1, and LS2 of the filter circuit 150 and the balun 160 schematically represent parasitic inductance at the ground, and the corresponding elements do not necessarily appear in an actual configuration.

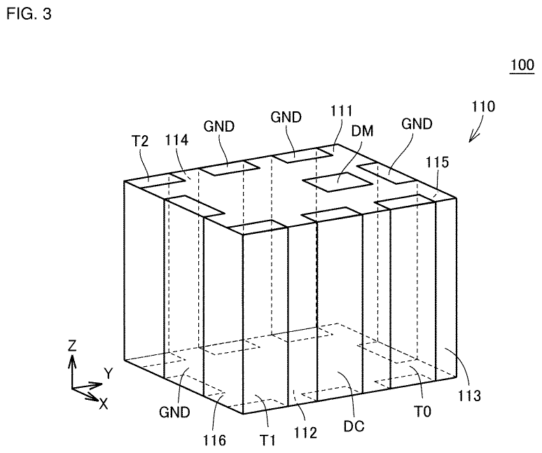

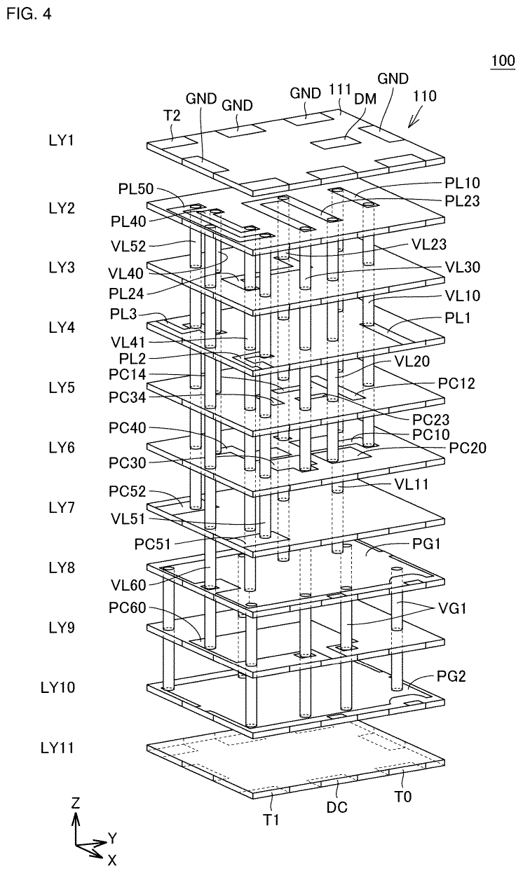

Next, a structure of the balanced filter 100 is described with reference to FIGS. 3 and 4. FIG. 3 is an external perspective view of the balanced filter 100 according to the present example embodiment. FIG. 4 is an exploded perspective view illustrating an example of a multilayer structure of the balanced filter 100 according to the present example embodiment.

As illustrated in FIGS. 3 and 4, the balanced filter 100 has a cuboid or substantially cuboid multilayer body 110 that is formed by laminating multiple dielectric layers LY1 to LY11 in a lamination direction. Each of the dielectric layers LY1 to LY11 includes a ceramic, such as, for example, a low temperature co-fired ceramic (LTCC), or a resin. Inside the multilayer body 110, the inductors and capacitors of the filter circuit 150 and the balun 160 include multiple electrodes provided on or in the dielectric layers and multiple vias provided between the dielectric layers. In the present application, “via” indicates a conductor provided in a dielectric layer to connect electrodes provided on or in different dielectric layers. For example, a via is made of a conductive paste, plating, and/or a metal pin.

In the descriptions below, a “Z-axis direction” indicates the lamination direction of the dielectric layers LY1 to LY11 of the multilayer body 110, an “X-axis direction” indicates a direction that is orthogonal or substantially orthogonal to the Z-axis direction and extends along one side of the multilayer body 110, and a “Y-axis direction” indicates a direction that extends along another side of the multilayer body 110. Also, in the descriptions below, the positive Z-axis direction and the negative Z-axis direction in each drawing may be referred to as “upper” and “lower”, respectively.

A directional mark DM to identify the orientation of the balanced filter 100 is provided on an upper surface 111 (dielectric layer LY1) of the multilayer body 110. Also, on the outer surface of the multilayer body 110, external terminals (unbalanced terminal T0, balanced terminals T1 and T2, direct-current power supply terminal DC, and ground terminals GND) with a C-shaped or substantially C-shaped cross section in the Z-axis direction are arranged to extend from the upper surface 111, through lateral surfaces, to a lower surface 112 (the dielectric layer LY11).

More specifically, on a lateral surface 113 (first long side) facing the positive X-axis direction, the balanced terminal T1, the direct-current power supply terminal DC, and the unbalanced terminal T0 are arranged in this order in the positive Y-axis direction. On a lateral surface 114 (second long side) facing the negative X-axis direction, the balanced terminal T2 and two ground terminals GND are arranged in this order in the positive Y-axis direction. A ground terminal GND is disposed on each of a lateral surface 115 (second short side) facing the positive Y-axis direction and a lateral surface 116 (first short side) facing the negative Y-axis direction.

Next, a structure related to the filter circuit 150 is described. On the lateral surface 113, the unbalanced terminal T0 is connected to a planar electrode PL1 that is disposed on or in the dielectric layer LY4. The planar electrode PL1 is, for example, a strip-shaped electrode extending in the X-axis direction, and a first end of the planar electrode PL1 is connected to the unbalanced terminal T0. A second end of the planar electrode PL1 is connected to a via VL10.

The via VL10 is connected to a planar electrode PL10 disposed on or in the dielectric layer LY2 and a capacitor electrode PC10 disposed on or in the dielectric layer LY6. The planar electrode PL10 is, for example, a strip-shaped electrode extending in the X-axis direction, and a first end of the planar electrode PL10 is connected to the via VL10. A second end of the planar electrode PL10 is connected through a via VL11 to a ground electrode PG1 that entirely or substantially entirely covers the dielectric layer LY8. The ground electrode PG1 is connected to the ground terminals GND on the lateral surfaces 114 and 115.

The ground electrode PG1 is also connected through multiple ground vias VG1 to a ground electrode PG2 that is disposed on or in the dielectric layer LY10. The ground electrode PG2 entirely or substantially entirely covers the dielectric layer LY10 and is connected to the ground terminals GND on the lateral surfaces 114 and 115. In plan view from the lamination direction, the multiple ground vias VG1 are arranged along the periphery of the multilayer body 110.

The capacitor electrode PC10 disposed on or in the dielectric layer LY6 is a crank-shaped or substantially crank-shaped planar electrode. The capacitor electrode PC10 opposes the ground electrode PG1 on or in the dielectric layer LY8. In plan view from the lamination direction (Z-axis direction), the capacitor electrode PC10 overlaps the ground electrode PG1. The capacitor electrode PC10 and the ground electrode PG1 define the capacitor C1 of the resonator RC1 illustrated in FIG. 2.

Also, the vias VL10 and VL11 and the planar electrode PL10 define the inductor L1 of the resonator RC1 illustrated in FIG. 2.

On or in the dielectric layer LY6, a capacitor electrode PC20 with a rectangular or substantially rectangular shape is spaced apart from the capacitor electrode PC10 in the positive X-axis direction. The capacitor electrode PC20 opposes the ground electrode PG1 on or in the dielectric layer LY8. In plan view from the lamination direction, the capacitor electrode PC20 overlaps the ground electrode PG1. The capacitor electrode PC20 and the ground electrode PG1 define the capacitor C2 of the resonator RC2 illustrated in FIG. 2.

The capacitor electrode PC20 is connected through a via VL20 to a planar electrode PL23 disposed on or in the dielectric layer LY2. The planar electrode PL23 is a C-shaped or substantially C-shaped strip electrode. A first end of the planar electrode PL23 is connected to the via VL20, and a second end of the planar electrode PL23 is connected to a via VL30. Also, a via VL23 is connected to an intermediate point of a path extending from the first end to the second end along the planar electrode PL23. The via VL23 is connected to the ground electrode PG1 on or in the dielectric layer LY8.

The vias VL20 and VL23 and a portion of the planar electrode PL23 between the via VL20 and the via VL23 define the inductor L2 of the resonator RC2 illustrated in FIG. 2.

The via VL30, which is connected to the first end of the planar electrode PL23, is connected to a capacitor electrode PC30 disposed on or in the dielectric layer LY6. The capacitor electrode PC30 is a planar electrode having a rectangular or substantially rectangular shape and is spaced apart from the capacitor electrode PC20 in the negative Y-axis direction. The capacitor electrode PC30 opposes the ground electrode PG1 on or in the dielectric layer LY8. In plan view from the lamination direction, the capacitor electrode PC30 overlaps the ground electrode PG1. The capacitor electrode PC30 and the ground electrode PG1 define the capacitor C3 of the resonator RC3 illustrated in FIG. 2.

The vias VL30 and VL23 and a portion of the planar electrode PL23 between the vias VL30 and VL23 define the inductor L3 of the resonator RC3 illustrated in FIG. 2.

The via VL23 is also connected to a planar electrode PL24 disposed on or in the dielectric layer LY3. The planar electrode PL24 is a crank-shaped or substantially crank-shaped strip electrode. A first end of the planar electrode PL24 is connected to the via VL23, and a second end of the planar electrode PL24 is connected to a via VL41. A first end of the via VL41 is connected to the ground electrode PG1 on or in the dielectric layer LY8, and a second end of the via VL41 is connected to a planar electrode PL40 disposed on or in the dielectric layer LY2. The planar electrode PL24 connects the resonators RC2, RC3, and RC4 to each other.

The planar electrode PL40 is a C-shaped or substantially C-shaped strip electrode that is disposed on the dielectric layer LY2. A first end of the planar electrode PL40 is connected to the via VL41, and a second end of the planar electrode PL40 is connected to a via VL40. The via VL40 is connected to a capacitor electrode PC40 disposed on or in the dielectric layer LY6.

The capacitor electrode PC40 is a crank-shaped or substantially crank-shaped planar electrode disposed on the dielectric layer LY6. The capacitor electrode PC40 is spaced apart from the capacitor electrode PC10 in the negative Y-axis direction and apart from the capacitor electrode PC30 in the negative X-axis direction. The capacitor electrode PC40 opposes the ground electrode PG1 on or in the dielectric layer LY8 and overlaps the ground electrode PG1 in plan view from the lamination direction. The capacitor electrode PC40 and the ground electrode PG1 constitute the capacitor C4 of the resonator RC4 illustrated in FIG. 2.

Also, capacitor electrodes PC12, PC23, PC34, and PC14 are disposed on or in the dielectric layer LY5. The capacitor electrode PC12 is a strip-shaped electrode extending in the X-axis direction and partially overlaps the capacitor electrodes PC10 and PC20 on or in the dielectric layer LY6 in plan view from the lamination direction. The capacitor electrodes PC10, PC20, and PC12 define the capacitor C12 in FIG. 2.

The capacitor electrode PC23 is a strip-shaped electrode extending in the Y-axis direction and partially overlaps the capacitor electrodes PC20 and PC30 on or in the dielectric layer LY6 in plan view from the lamination direction. The capacitor electrodes PC20, PC30, and PC23 define the capacitor C23 illustrated in FIG. 2.

The capacitor electrode PC34 is a strip-shaped electrode extending in the X-axis direction and partially overlaps the capacitor electrodes PC30 and PC40 on or in the dielectric layer LY6 in plan view from the lamination direction. The capacitor electrodes PC30, PC40, and PC34 define the capacitor C34 illustrated in FIG. 2.

The capacitor electrode PC14 is a strip-shaped electrode extending in the Y-axis direction and partially overlaps the capacitor electrodes PC10 and PC40 on or in the dielectric layer LY6 in plan view from the lamination direction. The capacitor electrodes PC10, PC40, and PC14 define the capacitor C14 illustrated in FIG. 2.

Next, a structure related to the balun 160 is described. The balanced terminal T1 is connected, at the lateral surface 113, to a planar electrode PL2 disposed on or in the dielectric layer LY4. The planar electrode PL2 is an L-shaped or substantially L-shaped strip electrode, and a first end of the planar electrode PL2 is connected to the unbalanced terminal T0. A second end of the planar electrode PL2 is connected to a via VL51.

A first end of the via VL51 is connected to a planar electrode PL50 disposed on or in the dielectric layer LY2, and a second end of the via VL51 is connected to a capacitor electrode PC51 disposed on or in the dielectric layer LY7. The capacitor electrode PC51 is a planar electrode having a rectangular or substantially rectangular shape and overlaps the ground electrode PG1 on or in the dielectric layer LY8 in plan view from the lamination direction. The capacitor electrode PC51 and the ground electrode PG1 define the capacitor CB1 illustrated in FIG. 2.

The planar electrode PL50 is a C-shaped or substantially C-shaped strip electrode, a first end of the planar electrode PL50 is connected to the via VL51, and a second end of the planar electrode PL50 is connected to a via VL52. The planar electrode PL40 of the resonator RC4 of the filter circuit 150 is disposed in the recess provided by the C-shape of the planar electrode PL50. The planar electrode PL40 and the planar electrode PL50 are disposed such that the opposing portions of the planar electrode PL40 and the planar electrode PL50 are parallel or substantially parallel to each other.

The via VL52 connected to the second end of the planar electrode PL50 is connected to a capacitor electrode PC52 disposed on or in the dielectric layer LY7. The capacitor electrode PC52 is a planar electrode with a rectangular or substantially rectangular shape and overlaps the ground electrode PG1 on or in the dielectric layer LY8 in plan view from the lamination direction. The capacitor electrode PC52 and the ground electrode PG1 define the capacitor CB2 illustrated in FIG. 2.

The via VL52 is also connected, at the lateral surface 114, to the balanced terminal T2 via an L-shaped or substantially L-shaped planar electrode PL3 disposed on or in the dielectric layer LY4.

A via VL60 is connected to an intermediate point of a path extending from the first end to the second end along the planar electrode PL50. The via VL60 is connected to a capacitor electrode PC60 disposed on or in a dielectric layer LY9. The capacitor electrode PC60 is connected, at the lateral surface 113, to the direct-current power supply terminal DC.

The capacitor electrode PC60 is a planar electrode with a rectangular or substantially rectangular shape and is disposed between the ground electrode PG2 on or in the dielectric layer LY10 and the ground electrode PG1 on or in the dielectric layer LY8. In plan view from the lamination direction, at least a portion of the capacitor electrode PC60 overlaps the ground electrode PG1 and the ground electrode PG2. Accordingly, the capacitor electrode PC60 and the ground electrodes PG1 and PG2 define the capacitor CB3 illustrated in FIG. 2.

The capacitor electrode PC60 and the via VL60 provide the path in FIG. 2 from the direct-current power supply terminal DC to the connection node N50 between the inductor LB1 and the inductor LB2 and correspond to a “direct-current power supply line” in the present disclosure. Also, the inductor LB1 in FIG. 2 is defined by the path that extends from the balanced terminal T1, through the planar electrode PL2, the via VL51, and the first end of the planar electrode PL50, to the via VL60. Furthermore, the inductor LB2 in FIG. 2 is defined by the path that extends from the balanced terminal T2, through the planar electrode PL3, the via VL52, and the second end of the planar electrode PL50, to the via VL60.

The inductors L5 and L6 of the filter circuit 150 and the inductors LS1 and LS2 of the balun 160 in FIG. 2 include inductance components of the paths that extend from the ground electrodes PG1 and PG2 through the ground vias VG1 to the ground terminals GND.

In a balanced filter as illustrated in FIG. 4 to which a direct-current power supply voltage is supplied, when inductors included in a filter circuit and/or a balun are electromagnetically coupled to a direct-current power supply line, characteristics, such as amplitude balance and a phase difference, for example, are influenced, and it becomes difficult to achieve desired filter characteristics of the balanced filter.

However, in the balanced filter 100 according to the present example embodiment, the capacitor electrode PC60 for the bypass capacitor included in the direct-current power supply line is disposed on or in a dielectric layer between two ground electrodes PG1 and PG2. Particularly, this configuration enables the ground electrode PG1 to define and function as a shield electrode and thus makes it possible to reduce or prevent the electromagnetic coupling between the capacitor electrode PC60 and each of the elements of the filter circuit 150 and the balun 160. This in turn makes it possible to reduce or prevent the influence on filter characteristics resulting from the electromagnetic coupling with the direct-current power supply line and to reduce or prevent the degradation of characteristics of the balanced filter.

Furthermore, in the balanced filter 100, the ground electrode PG1 and the ground electrode PG2 are connected to each other by multiple ground vias VG1. The ground vias VG1 make it possible to reduce or prevent the potential difference between the ground potentials of the ground electrode PG1 and the ground electrode PG2, make it possible to reduce the inductance values of parasitic inductors (the inductors L5, L6, LS1, and LS2 in the equivalent circuit in FIG. 2) that define and function as shunt inductors in the filter circuit 150 and the balun 160, and thus make it possible to improve the grounding characteristics of the ground electrodes PG1 and PG2. This makes it possible to reduce or prevent the degradation of characteristics caused by parasitic inductors.

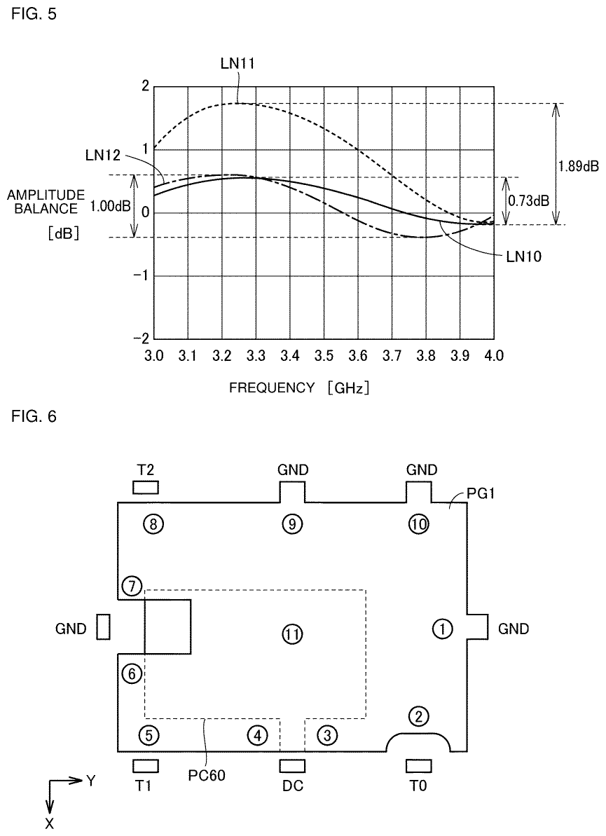

FIG. 5 is a diagram for describing the filter characteristics of the balanced filter 100 according to the present example embodiment. FIG. 5 is a graph showing the amplitude balance in filter characteristics in comparison with a case of a balanced filter of a comparative example.

In the graph of FIG. 5, the horizontal axis indicates a frequency, and the vertical axis indicates amplitude balance. A solid line LN10 represents the amplitude balance of the balanced filter 100 according to the present example embodiment, and a dotted line LN11 represents the amplitude balance of the balanced filter of the comparative example. Here, amplitude balance indicates a difference in power between signals input and output from the balanced terminal T1 and the balanced terminal T2.

Here, the balanced filter of the comparative example has a configuration that is obtained by removing the ground electrode PG1 from the configuration described with reference to the exploded perspective view of FIG. 4. In the case of the balanced filter of the comparative example, because the ground electrode PG1 defining and functioning as a shield is not included, the capacitor electrode PC60 in the direct-current power supply line may be electromagnetically coupled to elements of the filter circuit 150 and the balun 160 disposed above the capacitor electrode PC60.

As shown in FIG. 5, in a desired frequency band (for example, from about 3.0 GHz to about 4.0 GHz), while the variation in the amplitude balance of the balanced filter of the comparative example is about 1.89 dB (dotted line LN11), the variation in the amplitude balance of the balanced filter 100 of the example embodiment is reduced to about 0.73 dB (solid line LN10).

For reference, FIG. 5 also shows the amplitude balance (dashed-dotted line LN12) of a balanced filter with a configuration that includes the ground electrode PG1 but does not include the ground vias VG1 connecting the ground electrode PG1 to the ground electrode PG2. The amplitude balance of this configuration is, for example, about 1.00 dB. Thus, the amplitude balance of this configuration is improved over the comparative example not including the ground electrode PG1, but not as much as the amplitude balance of the balanced filter 100 of the present example embodiment in which the ground electrode PG1 is connected to the ground electrode PG2.

Thus, it is possible to further improve the amplitude balance by providing the capacitor electrode PC60 of the direct-current power supply line on or in a dielectric layer between the ground electrodes PG1 and PG2 that are interconnected by multiple ground vias VG1.

As illustrated in FIG. 5, connecting the ground electrodes PG1 and PG2 with multiple ground vias VG1 improves the amplitude balance compared with a case in which the ground electrodes PG1 and PG2 are not connected to each other.

Here, the inventors of example embodiments of the present invention have discovered that even when the ground electrodes PG1 and PG2 are connected to each other with the ground vias VG1, the advantageous effect of improving the amplitude balance varies depending on the positions of the ground vias VG1. Changes in the filter characteristics depending on the positions of the ground vias VG1 connecting the two ground electrodes PG1 and PG2 are described with reference to FIGS. 6 to 8.

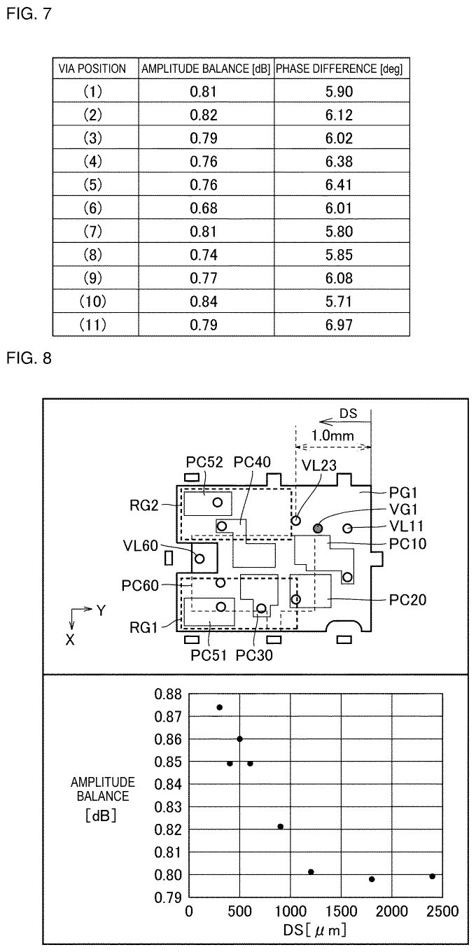

FIGS. 6 and 7 are diagrams for describing simulation results for filter characteristics obtained by varying the position of the ground via VG1 in the configuration of the balanced filter 100.

FIG. 6 is a diagram illustrating the via positions of the ground via VG1 in the ground electrode PG1 in plan view of the balanced filter 100 from the positive Z-axis direction. In FIG. 6, numbers 1 to 11 are assigned to the via positions of the ground via. FIG. 7 shows the amplitude balance and the phase difference at each of the via positions of the ground via illustrated in FIG. 6. Each simulation assumes that a single ground via VG1 is provided at the corresponding position.

Smaller values of the amplitude balance and the phase difference indicate better filter characteristics. Referring to FIG. 7, better amplitude balance can be achieved in a case in which the ground via VG1 is disposed on a side of the ground electrode PG1 closer to the balanced terminals T1 and T2 (negative Y-axis side) than in a case in which the ground via VG1 is disposed on a side of the ground electrode PG1 closer to the unbalanced terminal T0 (positive Y-axis side).

Specifically, in FIG. 7, the amplitude balance at each of the via positions (4), (5), (6), and (8) is relatively good. This may be because the inductance values of the inductors LS1 and LS2 corresponding to parasitic inductors of the balun 160 in FIG. 2 are reduced by placing the ground via VG1 on a side closer to the balanced terminals T1 and T2.

FIG. 8 is a diagram for describing a relationship between the amplitude balance and a distance DS from a short side (second short side) of the multilayer body 110 closer to the unbalanced terminal T0 to the ground via VG1. The upper portion of FIG. 8 illustrates an example of a layout of elements near the ground electrode PG1 and a position of the ground via VG1 in plan view of the multilayer body 110 from the positive Z-axis direction. The lower portion of FIG. 8 is a graph showing simulation results for the amplitude balance obtained by varying the distance DS. Also in FIG. 8, each simulation assumes that a single ground via VG1 is placed at the corresponding position.

As shown in the graph of FIG. 8, as the distance DS increases, that is, as the ground via VG1 is located closer to a short side (first short side) that is closer to the balanced terminals T1 and T2, the amplitude balance decreases. However, when the distance DS exceeds, for example, about 1000 μm, the amplitude balance converges to, for example, about 0.80 dB.

In an exemplary balanced filter used for the simulations of FIG. 8, the dimension of the multilayer body 110 in the Y-axis direction is, for example, about 3.2 mm, and the distance DS to the via VL23 of the inductors of the resonators RC2 and RC3 is, for example, about 1.0 mm. Accordingly, in the configuration of the balanced filter 100 of the present example embodiment, the ground via VG1 is preferably located in regions RG1 and RG2 in the upper portion of FIG. 8.

That is, the regions RG1 and RG2 are closer to the balanced terminals than the via VL23 and are closer to the corresponding long sides than a notch provided in the ground electrode PG1 for the via VL60. In the example of FIG. 7, the via positions (3) to (9) are located in the regions RG1 and RG2. Among these via positions, the via positions (5) to (8) are disposed in regions that are included in the regions RG1 and RG2 and located between the balanced terminal T1 and the balanced terminal T2.

In the balanced filter 100 of the present example embodiment, in plan view from the lamination direction, the balanced terminals T1 and T2 are arranged symmetrically or substantially symmetrically with respect to a virtual line that passes through the midpoint of the short side (first short side) of the multilayer body 110 closer to the balanced terminals T1 and T2 and extends along the Y-axis. The planar electrode PL50 and the vias VL51 and VL52 defining the balun 160 are also symmetrical or substantially symmetrical with respect to the virtual line described above. Therefore, when placing the ground vias VG1 in regions near the balanced terminals T1 and T2, it is preferable to arrange the ground vias VG1 symmetrically or substantially symmetrically with respect to the virtual line. Symmetrically or substantially symmetrically arranging the ground vias VG1 in this manner makes it possible to equalize the influence of the ground vias VG1 on the balanced terminals and thus makes it possible to effectively improve the amplitude balance.

For example, in FIG. 6, ground vias VG1 may be located at the positions (6) and (7) and/or the positions (5) and (8). When placing ground vias VG1 at the positions (6) and (7) near the notch of the ground electrode PG1, the ground vias VG1 may be arranged such that the via VL60 of the direct-current power supply line is disposed between two ground vias VG1.

When providing ground vias VG1 at the positions (5) and (8) near the balanced terminals T1 and T2, the ground vias VG1 may be disposed to overlap the capacitor electrodes PC51 and PC52 for the shunt capacitors of the balun 160 in plan view from the lamination direction.

Also, when the ground vias VG1 are arranged symmetrically or substantially symmetrically, the ground terminals GND disposed on the short sides are located between two ground vias VG1 in the view of the multilayer body 110 along the Y-axis direction.

As described above, filter characteristics can be improved by configuring a balanced filter such that a portion of the direct-current power supply line is disposed between two ground electrodes PG1 and PG2, and the ground electrodes PG1 and PG2 are connected to each other by using at least two ground vias VG1 that are arranged symmetrically or substantially symmetrically on a side closer to the balanced terminals T1 and T2.

In the resonators RC1 to RC4, the vias VL11, VL23, and VL41, which are connected to the ground electrode PG1, may also be connected to the ground electrode PG2 in addition to the ground electrode PG1. In this case, these vias also define and function as the ground vias VG1.

Furthermore, one or more ground electrodes may be provided in addition to the ground electrodes PG1 and PG2. Parasitic capacitance can be adjusted by increasing the number of ground electrodes.

“Balanced terminal T1” and “balanced terminal T2” in the present example embodiment correspond to “first balanced terminal” and “second balanced terminal” in the present disclosure, respectively. “Ground electrode PG1” and “ground electrode PG2” in the present example embodiment correspond to “first ground electrode” and “second ground electrode” in the present disclosure, respectively. “Inductor LB1” and “inductor LB2” in the present example embodiment correspond to “first inductor” and “second inductor” in the present disclosure, respectively. “Connection node N50” in the present example embodiment corresponds to “connection node” in the present disclosure. “Upper surface 111” and “lower surface 112” in the present example embodiment correspond to “first major surface” and “second major surface” in the present disclosure, respectively. “Via VL60” in the present example embodiment corresponds to “power supply via” in the present disclosure. “Resonators RC1 to RC4” in the present example embodiment correspond to “first resonator” through “fourth resonator” in the present disclosure, respectively. “Capacitor electrode PC51” and “capacitor electrode PC52” in the present example embodiment correspond to “first capacitor electrode” and “second capacitor electrode” in the present disclosure, respectively.

In the balanced filter 100 of the present example embodiment, the balanced terminals T1 and T2 face each other at two opposing long sides of the multilayer body 110. However, the arrangement of external terminals is not limited to this example.

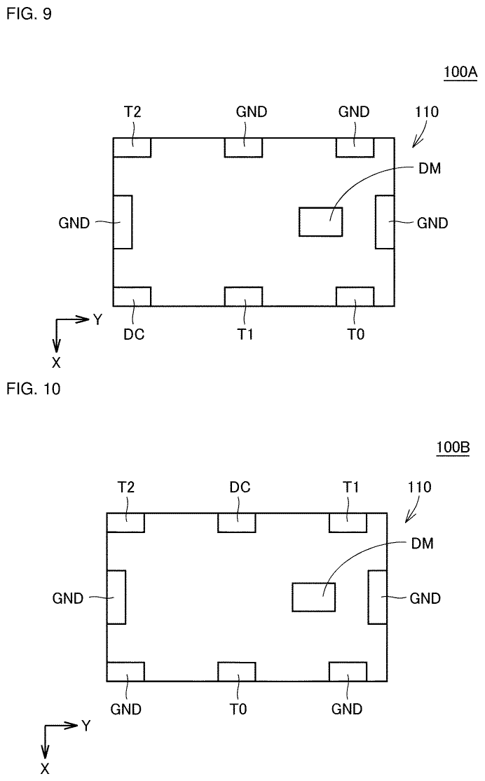

For example, as in a balanced filter 100A of a first variation of an example embodiment of the present invention in FIG. 9, the positions of the balanced terminal T1 and the direct-current power supply terminal DC may be exchanged such that the balanced terminal T1 and the balanced terminal T2 do not face each other.

Also, as in a balanced filter 100B of a second variation of an example embodiment of the present invention in FIG. 10, the balanced terminals T1 and T2 may be arranged symmetrically or substantially symmetrically with respect to the direct-current power supply terminal DC along a long side of the multilayer body 110, and the unbalanced terminal T0 may be disposed on the opposing long side to face the direct-current power supply terminal DC.

Also in the configurations of the balanced filters 100A and 100B, by locating the capacitor electrode PC60 defining a portion of the direct-current power supply line on or in a dielectric layer between the ground electrodes PG1 and PG2 connected to each other by multiple ground vias VG1, it is possible to reduce or prevent degradation of the characteristics of the balanced filters.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A balanced filter comprising:
a multilayer body including a first major surface and a second major surface facing each other and including multiple dielectric layers that are laminated;
an unbalanced terminal, a first balanced terminal, a second balanced terminal, a direct-current power supply terminal, and a ground terminal on an outer surface of the multilayer body;
a filter circuit connected to the unbalanced terminal and including multiple resonators in the multilayer body;
a balun connected to the first balanced terminal and the second balanced terminal to convert balanced signals into an unbalanced signal;
a first ground electrode with a planar shape, provided on or in a dielectric layer between the filter circuit and the second major surface, and connected to the ground terminal;
a second ground electrode with a planar shape, provided on or in a dielectric layer between the first ground electrode and the second major surface, and connected to the ground terminal; and
multiple ground vias connecting the first ground electrode to the second ground electrode; wherein
the balun includes:
a first inductor and a second inductor electromagnetically coupled to at least one of the multiple resonators of the filter circuit and connected, respectively, to the first balanced terminal and the second balanced terminal; and
a direct-current power supply line connected between the direct-current power supply terminal and a connection node between the first inductor and the second inductor; and
a portion of the direct-current power supply line is provided on or in a dielectric layer between the first ground electrode and the second ground electrode.

2. The balanced filter according to claim 1, wherein
the direct-current power supply line includes:
a planar electrode connected to the direct-current power supply terminal and provided on or in a dielectric layer between the first ground electrode and the second ground electrode; and
a power supply via connected to the planar electrode and the connection node.

3. The balanced filter according to claim 2, wherein
in plan view from a lamination direction of the multiple dielectric layers, the multilayer body has a rectangular or substantially rectangular shape including a first long side and a second long side facing each other and a first short side and a second short side facing each other;
the first balanced terminal is located on the first long side closer to the first short side;
the second balanced terminal is located on the second long side closer to the first short side to face the first balanced terminal;
the multiple ground vias include a first via electrode and a second via electrode; and
in plan view from the lamination direction, the first via electrode and the second via electrode are located in regions between the first balanced terminal and the second balanced terminal.

4. The balanced filter according to claim 3, wherein
the balun further includes:
a first capacitor electrode connected to an end of the first inductor and facing the first ground electrode; and
a second capacitor electrode connected to an end of the second inductor and facing the first ground electrode; and
in plan view from the lamination direction, the first via electrode overlaps the first capacitor electrode, and the second via electrode overlaps the second capacitor electrode.

5. The balanced filter according to claim 3, wherein
the first via electrode, the second via electrode, and the power supply via are arranged along the first short side; and
in plan view from the lamination direction, the power supply via is located in a region between the first via electrode and the second via electrode.

6. The balanced filter according to claim 4, wherein the first via electrode and the second via electrode are arranged symmetrically or substantially symmetrically with respect to a virtual line passing through a midpoint of the first short side and parallel or substantially parallel to the first long side.

7. The balanced filter according to claim 3, wherein
the ground terminal is provided on the first short side; and
in a view of the multilayer body from the first short side, the ground terminal is located between the first via electrode and the second via electrode.

8. The balanced filter according to claim 3, wherein
the multiple resonators of the filter circuit include a first resonator, a second resonator, a third resonator, and a fourth resonator;
the first resonator is connected to the unbalanced terminal; and
the fourth resonator is electromagnetically coupled to the balun.

9. The balanced filter according to claim 8, wherein, in plan view from the lamination direction, the first via electrode and the second via electrode are located in a region between a via included in the second resonator and the first short side.

10. The balanced filter according to claim 8, wherein, when a first direction denotes a direction from the second short side toward the first short side, in plan view of the multilayer body from the lamination direction, the first via electrode and the second via electrode are spaced apart from the second short side by about 1.0 mm or more in the first direction.

11. The balanced filter according to claim 3, wherein the unbalanced terminal is provided on the first long side between the first balanced terminal and the second short side.

12. The balanced filter according to claim 11, wherein the direct-current power supply terminal is provided on the first long side between the unbalanced terminal and the first balanced terminal.

13. A communication device comprising:
an antenna;
a power amplifier;
the balanced filter according to claim 1; and
an RF circuit.

14. The communication device according to claim 13, wherein the direct-current power supply line includes:
a planar electrode connected to the direct-current power supply terminal and provided on or in a dielectric layer between the first ground electrode and the second ground electrode; and
a power supply via connected to the planar electrode and the connection node.

15. The communication device according to claim 14, wherein
in plan view from a lamination direction of the multiple dielectric layers, the multilayer body has a rectangular or substantially rectangular shape including a first long side and a second long side facing each other and a first short side and a second short side facing each other;
the first balanced terminal is located on the first long side closer to the first short side;
the second balanced terminal is located on the second long side closer to the first short side to face the first balanced terminal;
the multiple ground vias include a first via electrode and a second via electrode; and
in plan view from the lamination direction, the first via electrode and the second via electrode are located in regions between the first balanced terminal and the second balanced terminal.

16. The communication device according to claim 15, wherein
the balun further includes:
a first capacitor electrode connected to an end of the first inductor and facing the first ground electrode; and
a second capacitor electrode connected to an end of the second inductor and facing the first ground electrode; and
in plan view from the lamination direction, the first via electrode overlaps the first capacitor electrode, and the second via electrode overlaps the second capacitor electrode.

17. The communication device according to claim 15, wherein
the first via electrode, the second via electrode, and the power supply via are arranged along the first short side; and
in plan view from the lamination direction, the power supply via is located in a region between the first via electrode and the second via electrode.

18. The communication device according to claim 16, wherein the first via electrode and the second via electrode are arranged symmetrically or substantially symmetrically with respect to a virtual line passing through a midpoint of the first short side and parallel or substantially parallel to the first long side.

19. The communication device according to claim 15, wherein
the ground terminal is provided on the first short side; and
in a view of the multilayer body from the first short side, the ground terminal is located between the first via electrode and the second via electrode.

20. The communication device according to claim 15, wherein
the multiple resonators of the filter circuit include a first resonator, a second resonator, a third resonator, and a fourth resonator;
the first resonator is connected to the unbalanced terminal; and
the fourth resonator is electromagnetically coupled to the balun.
